(19) United States
(12) Patent Application Publication
(10) Pub. No.: US 2008/0028271 A1
(43) Pub. Date: Jan. 31, 2008

(54) METHOD FOR GENERATING LDPC CODE FOR A LDPC BASED TDS-OFDM SYSTEM

(75) Inventor: Lei Chen, San Jose, CA (US)

Correspondence Address: FRANKLIN (LIN) YANG, 91 CANTERBURY GATE, LYNBROOK, NY, 11563, US

(73) Assignee: LEGEND SILICON, FREMONT, CA (US)

(21) Appl. No.: 11/550,567

(22) Filed: Oct. 18, 2006

Related U.S. Application Data
(60) Provisional application No. 60/820,313, filed on Jul. 25, 2006.

(51) Int. Cl. H03M 13/00

(52) U.S. Cl. 714/752

(57) ABSTRACT

In a LDPC based communications system, a method for generating LDPC codes is provided. The method comprises the steps of: constructing a base matrix; providing a plurality of sub-matrices for forming the base matrix, with each sub-matrix being a cyclic permutation matrix; and masking the base matrix using a small sparse matrix.

### REFERENCE TO RELATED APPLICATIONS

This application claims an invention which was disclosed in Provisional Application No. 60/820,313, filed Jul. 25, 2006 entitled “LDPC Code of Various Rates for a[n] LDPC BASED TDS-OFDM Communication System and Code Generation Method thereof”. The benefit under 35 USC § 119(e) of the United States provisional application is hereby claimed, and the aforementioned application is hereby incorporated herein by reference.

### FIELD OF THE INVENTION

The present invention relates generally to communication methods. More specifically, the present invention relates a new method for generating LDPC (Low Density Parity Check) code for a LDPC BASED TDS-OFDM system.

### BACKGROUND

OFDM (Orthogonal frequency-division multiplexing) is known. U.S. Pat. No. 3,488,445 to Chang describes an apparatus and method for frequency multiplexing of a plurality of data signals simultaneously on a plurality of mutually orthogonal carrier waves such that overlapping, but band-limited, frequency spectra are produced without causing interchannel and intersymbol interference. Amplitude and phase characteristics of narrow-band filters are specified for each channel in terms of their symmetries alone. The same signal protection against channel noise is provided as though the signals in each channel were transmitted through an independent medium and intersymbol interference were eliminated by reducing the data rate. As the number of channels is increased, the overall data rate approaches the theoretical maximum.

OFDM transreceivers are known. U.S. Pat. No. 5,282,222 to Fattouche et al describes a method for allowing a number of wireless transceivers to exchange information (data, voice or video) with each other. A first frame of information is multiplexed over a number of wideband frequency bands at a first transceiver, and the information transmitted to a second transceiver. The information is received and processed at the second transceiver. The information is differentially encoded using phase shift keying. In addition, after a pre-selected time interval, the first transceiver may transmit again. During the preselected time interval, the second transceiver may exchange information with another transceiver in a time duplex fashion. The processing of the signal at the second transceiver may include estimating the phase differential of the transmitted signal and pre-distorting the transmitted signal. A transceiver includes an encoder for encoding information, a wideband frequency division multiplexer for multiplexing the information onto wideband frequency voice channels, and a local oscillator for upconverting the multiplexed information. The apparatus may include a processor for applying a Fourier transform to the multiplexed information to bring the information into the time domain for transmission.

Using PN (pseudo-noise) as the guard interval in an OFDM is known. U.S. Pat. No. 7,072,289 to Yang et al describes a method of estimating timing of at least one of the beginning and the end of a transmitted signal segment in the presence of time delay in a signal transmission channel. Each of a sequence of signal frames is provided with a pseudo-noise (PN) m-sequences, where the PN sequences satisfy selected orthogonality and closures relations. A convolution signal is formed between a received signal and the sequence of PN segments and is subtracted from the received signal to identify the beginning and/or end of a PN segment within the received signal. PN sequences are used for timing recovery, for carrier frequency recovery, for estimation of transmission channel characteristics, for synchronization of received signal frames, and as a replacement for guard intervals in an OFDM context.

LDPC (Low Density Parity Check) code systems are known. United States published patent application No. 20060156206 to Shen et al. describes a algebraic construction of LDPC codes with corresponding parity check matrix having CSI (Cyclic Shifted Identity) sub-matrices. Identity sub-matrices undergo cyclic shifting, thereby generating CSI sub-matrices that are arranged forming a parity check matrix of an LDPC code. The parity check matrix of the LDPC code may correspond to a regular LDPC code, or the parity check matrix of the LDPC code may undergo further modification to transform it to that of an irregular LDPC code. The parity check matrix of the LDPC code may be partitioned into 2 sub-matrices such that one of these 2 sub-matrices is transformed to be a block dual diagonal matrix; the other of these 2 sub-matrices may be modified using a variety of means, including the density evolution approach, to ensure the desired bit and check degrees of the irregular LDPC code.

As can be seen, LDPC code has qualities that are preferred over Turbo-codes. Furthermore, LDPC code can be further improved to suit a TDS-OFDM communications system. Therefore, it is desirous to have improved LDPC codes and a method and device to generate same.

### SUMMERY OF THE INVENTION

In a LDPC BASED TDS-OFDM system, a novel quasi-cyclic parity-check (H) matrix is provided.

In a LDPC BASED TDS-OFDM system, a quasi-cyclic generator (G) matrix is derived from the novel parity-check (H) matrix.

A novel construction of LDPC codes in a LDPC based TDS-OFDM system is provided.

A novel construction of LDPC codes in a LDPC based TDS-OFDM system provided, with the construction based upon the minimum-weight codewords of Reed-Solomon codes.

A novel construction of LDPC codes in a LDPC based TDS-OFDM system in which the codes are generated using the quasi-cyclic characteristics therein.

A novel construction of LDPC codes in a LDPC based TDS-OFDM system in which the codes are generated using the quasi-cyclic characteristics therein including the usage of simple shift-registers therefore.

A novel construction of LDPC codes in a LDPC based TDS-OFDM system with encoding complexity linearly proportional to the length of the code for parallel encoding and to the number of parity bits for serial encoding is provided.

A novel construction of LDPC codes in a LDPC based TDS-OFDM system in which a method optimizes the degree distributions of check nodes and bit nodes to make the error-floor lowered to such level as 10⁻¹² is provided.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of a Tanner graph associated with a LDPC decoder with some embodiments of the invention.

FIG. 2 is an example of a parity check matrix of the present invention.

FIG. 3 is a first example of a flowchart of the present invention.

FIG. 4A is a first example of an experimental parity check matrix.

FIG. 4B is a second example of an experimental parity check matrix.

FIG. 4C is a third example of an experimental parity check matrix.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to generate a code that possesses significantly, improved performances such as significantly lowered error floor to lower than 10⁻¹², as well as ignorantly reducing the complexity of the encoding and decoding implementation or hardware. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of generating a code that possesses significantly, improved performances such as significantly lowered error floor to lower than 10⁻², as well as ignorantly reducing the complexity of the encoding and decoding implementation or hardware. described herein. The non-processor circuits may include, but are not limited to, a radio receiver, a radio transmitter, signal drivers, clock circuits, power source circuits, and user input devices. As such, these functions may be interpreted as steps of a method to perform the generation a code that possesses significantly, improved performances such as significantly lowered error floor to lower than 10⁻¹², as well as ignorantly reducing the complexity of the encoding and decoding implementation or hardware. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

LDPC codes are a class of Shannon-limit approaching codes. Since they possess amazingly good performances, LDPC codes have been and will be widely used in a variety of communications systems, especially performance demanding systems. LDPC design methodology can generally be classified into two categories, namely random LDPC codes and structured LDPC codes. The design of random LDPC codes normally relies on massive computer searches under varies constraints deduced from graph structures. The design of structured LDPC codes is based on algebraic and combinatorial methods. Well designed structured LDPC codes can perform just as well as random LDPC codes in terms of bit-error probability, block-error probability, error-floor and decoding convergence rate collectively. In fact, structured LDPC codes in general have a lower error-floor, which is important in digital communication systems, where very low error rates are required. Structured codes with large minimum distances can be constructed much easier than computer generated random codes. Furthermore, structured codes, such as quasi-cyclic LDPC codes, have encoding advantage over other types of LDPC codes. Encoding of these structured codes can be implemented using simple shift-registers with linear complexity in contrast to the quadratic complexity involved in computer generated random LDPC codes. These codes also have advantages in decoder implementation due to their quasi-cyclic structure. The advantages are described in detail infra.

As can be seen, the lack or the want of good structures are the main drawbacks or disadvantages of the random LDPC codes. One reason for the disadvantage is that because of the fact that the implementation complexity of the concomitant encoder and decoder is usually pretty high. So high that sometimes causes the implementation to be significantly more expensive than structured LDPC codes. On the contrary, structured LDPC codes have great advantages over random LDPC codes at least in this aspect.

LDPC codes can also be classified as regular LDPC codes and irregular LDPC codes according to their matrices structures. Regular LDPC codes are the class of codes whose parity-check (H) matrices have constant row weights and constant column weights. Irregular LDPC codes are the class of codes whose parity-check matrices don't have constant row weights or constant column weights. For codes with short cycles, iterative decoding becomes correlated after two iterations, and decoding either does not converge or converges slowly. Therefore, cycles of length 4 is undesirable and should be avoided or removed in a code construction. It should be noted that the distribution of “1”s in the parity-check matrix has great impact of the performance of the corresponding LDPC codes. It is noted that the present invention contemplates using irregular LDPC codes.

Generally speaking, the bit error rate (BER) curve of the irregular LDPC codes can be closer to the theoretical Shannon limit than that of regular LDPC codes under same constraints. Put it another way, irregular LDPC codes have better performances than regular ones in terms of the capability to approach theoretical limit. On the other hand, the error floor of the irregular LDPC codes is normally higher than that of the regular LDPC codes. Since the BER requirement is below 10⁻¹² in digital television broadcasting system, it would be ideal if the LDPC codes can both approach the Shannon limit as good as irregular codes and also have low error floor as regular codes.

Recent research shows that the goal to approach Shannon limit and the goal to have low error floor are conflicting. In another words, the closer to the Shannon limit the BER curve, the higher the error floor and vice versa. Therefore, the excellent performance of low Signal-to-Noise Ratio (SNR) is normally attained at the expense of a high error floor. The present invention contemplates a trade off regarding these two conflicting goals by using various design methods in the design of LDPC codes in a communications system such as in a DMB-TH system, thereby making the bit error rate curve further from the Shannon limit just a little bit while no error in the range of the given bit error rate shows up.

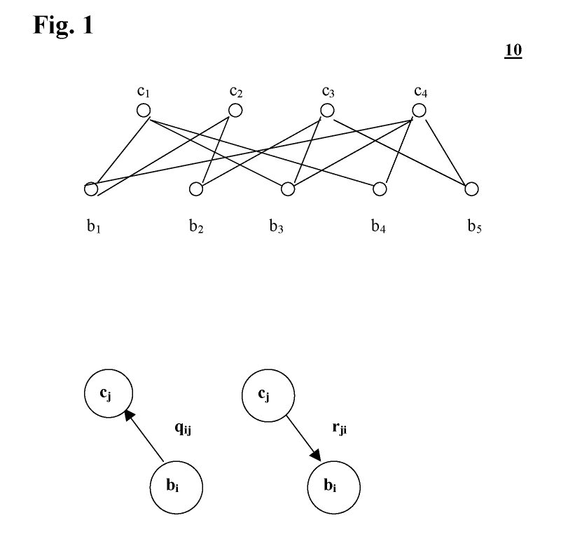

The construction of LDPC codes in DMB-TH system is based on the minimum-weight codewords of Reed-Solomon codes and at the same time optimizes the degree distributions of the bit nodes and check nodes of their corresponding Tanner graphs to make the error-floor lower than 10⁻¹². A Tanner graph is shown in FIG. 1.

Referring to FIG. 1, a Tanner graph 10 based LDPC decoder is shown. As can be seen, the decoding process of a low density parity check (LDPC) code can be described by a Tanner graph as shown in FIG. 1. The cⱼ are defined as check nodes, and the bᵢ are defined as bit nodes. Note the interrelationships from cⱼ to bᵢ are referred to as rⱼᵢ, and bᵢ to cⱼ as qᵢⱼ. Tanner graph is a popular way to describe LDPC decoder.

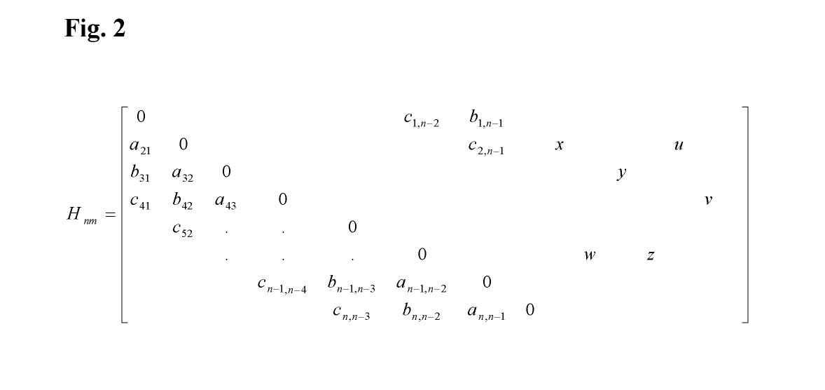

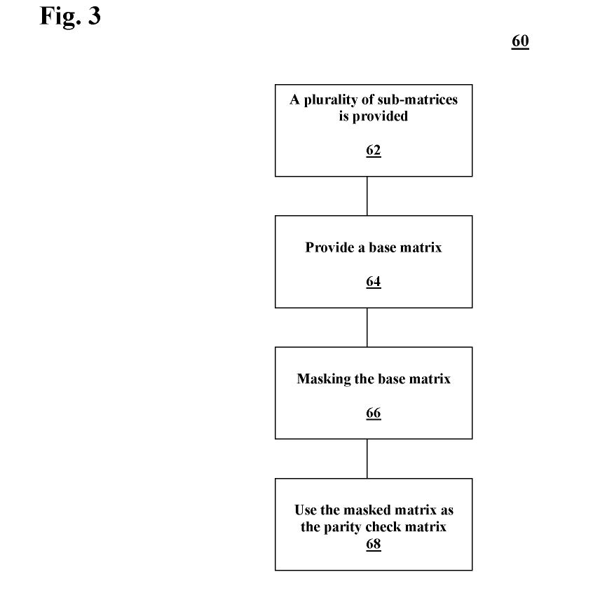

Referring to FIGS. 2-3, the codes generated in the present invention are quasi-cyclic. Their generator matrices and parity-check matrices comprises a multiplicity of sub-matrices. Each sub-matrix is a cyclic matrix, called a circulant. The quasi-cyclic structure makes it possible to implement the encoding of the LDPC codes with simple shift registers and logic circuits. Moreover, the quasi-cyclic structure reduces the implementation complexity of the decoding drastically, thus effectively lowering the cost of same in operation and usage.

Based on the minimum-weight codewords of Reed-Solomon codes, a m×n array Hᵣₛ of (b−1)×(b−1) circulant can be formed, where 1<m≦n, and b is a power of a prime number (e.g. b=127) as shown below:

$${H}_{rs} = [ \begin{matrix}0 & {A}_{1 , 2} & ⋯ & {A}_{1 , m} & {A}_{1 , m + 1} & ⋯ & {A}_{1 , n} \\ {A}_{2 , 1} & 0 & ⋯ & {A}_{2 , m} & {A}_{2 , m + 1} & ⋯ & {A}_{2 , n} \\ ⋮ & ⋮ & ⋮ & ⋮ & ⋮ & ⋮ & ⋮ \\ {A}_{m , 1} & {A}_{m , 2} & ⋯ & 0 & {A}_{m , m + 1} & ⋯ & {A}_{m , n}\end{matrix} ]$$

For Hᵣₛ, each of the first m columns of the array Hᵣₛ contains one zero circulant, and each of the other n-m columns of Hᵣₛ contains m (b−1)×(b−1) circulant permutation matrices. Therefore, Hᵣₛ is a m(b−1)×n(b−1) matrix over GF(2) with m(b−1) columns of weight m−1 and (n−m)(b−1) columns of weight m. All the rows of Hᵣₛ have weight n−1. It follows that according to the structural properties of the uniform classes of minimum-weight codewords of Reed-Solomon codes and their symbol location vectors that no two rows (or two columns) of Hᵣₛ have more than one 1-component in common. This ensures that the Tanner graph of Hᵣₛ does not contain cycles of length 4. Hᵣₛ is known as a base matrix.

Base matrix Hᵣₛ may be constructed as follows. Consider the (q−1, 2, q−2) cyclic RS code C_{b} over GF(q). Each m-w codeword in C_{b} has one and only one 0-component and two m-w codewords have at most one position with the same code symbol. Let vᵢ=(v_{i,0}, v_{i,1}, . . . v_{i,q-2}) be a m-w codeword in C_{b} whose j^{th} component vᵢⱼ=0. For 0≦i<q−1, let Qᵢ={vᵢ, αvᵢ, . . . α^{q-2}vᵢ}. It is clear that the i^{th} component of each m-w codeword in Qᵢ is zero. Qᵢ is called a uniform class of m-w codewords of C_{b}. Two uniform classes are disjoint and therefore the (q−1)² m-w codewords of C_{b} are partitioned into (q−1) uniform classes, Q₀, . . . , Q_{q-1}. For 0≦i, j<q−1, representing each code symbol of a m-w codeword α^{j}vᵢ in Qᵢ by its location vector, we obtain a (q−1)²-tuple z(α^{j}vᵢ) over GF(2) with weight q−2, which is called the symbol location vector of α^{j}vᵢ. For 0≦i<q−1, form a (q−1)(q−1)² matrix Bᵢ with the symbol location vectors of the m-w codewords in Qᵢ as the rows. Then Bᵢ=(A_{i,0}, A_{i,1}, . . . A_{i,q-2}) consists of a row of (q−1)×(q−1) circulants permutation matrices and one zero matrix A_{i,i} which can be regarded as a circulant. Form a (q−1)×(q−1) array Hᵣₛ=[A_{i,j}] (q−1)×(q−1) circulants with B₀, B₁, . . . B_{q-2} as submatrices arranged in a column. Hᵣₛ is a (q−1)²(q−1)² matrix over GF(2).

After a base matrix Hᵣₛ consisting of an array of circulant permutation matrices of the same size is constructed, a masking technique will be used. In the masking technique, a relatively small sparse matrix Z over GF(2) with a properly designed distribution of 1-entries is constructed for the masking action. In order to mask the base matrix Hᵣₛ with Z, a masked matrix H=M=Z\textcircled{x}Hᵣₛ is firstly obtained. The masked matrix M consists of an array of circulant permutation matrices and zero matrices of the same size. The masking matrix Z is constructed based on the bit-node and check-node degree distributions of the code graph such as the Tanner graph of FIG. 1. The masking technique of the present invention significantly simplifies the random construction of irregular LDPC codes. The masking technique also avoids the random edge selection process in the construction of the code graph as needed in computer generation of irregular LDPC codes based on the degree distributions of graph nodes. The null space of the masked matrix M gives an irregular LDPC code of length n×(b−1) with rate (n−m)/n (Step 24). Note that the operand \textcircled{x} does not stand for matrix multiplication. Instead, the operand \textcircled{x} stands for a selection process where, for example, some of the elements of Hᵣₛ are set to zero by the mask Z. By way of the practical example, assuming:

$${H}_{rs} = ( \begin{matrix}0 & d & e \\ a & 0 & 0 \\ c & b & 0\end{matrix} )$$

and the masking matrix

$$Z = ( \begin{matrix}0 & 0 & 0 \\ 1 & 0 & 0 \\ 1 & 1 & 0\end{matrix} )$$

the end result of

$${ZH}_{rs} = ( \begin{matrix}0 & 0 & 0 \\ a & 0 & 0 \\ c & b & 0\end{matrix} )$$

In other words, other than the a, b, and c elements, the resultant, masked matrix all zeros.

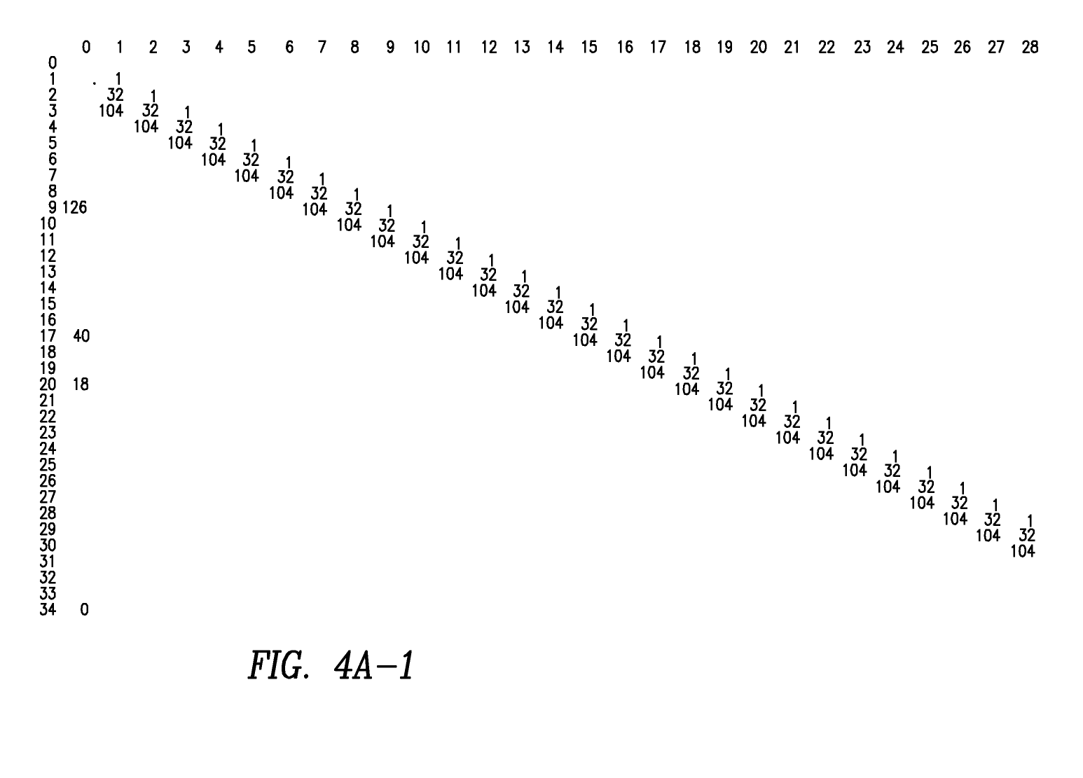

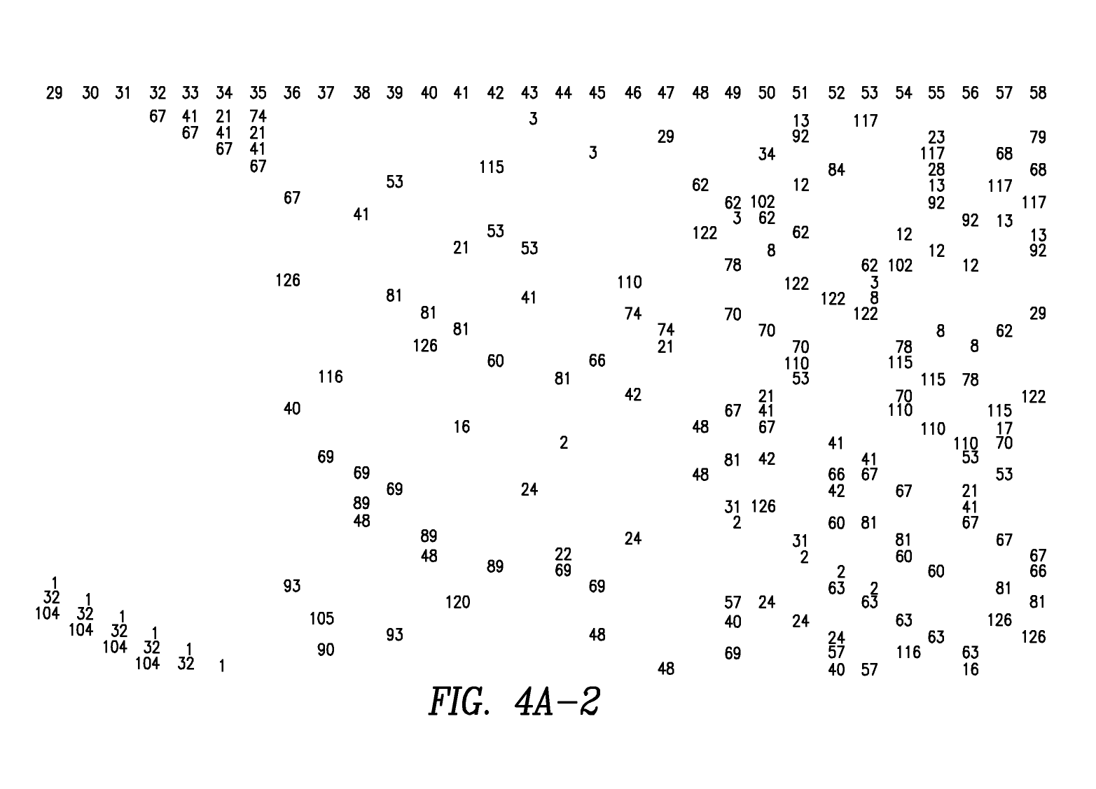

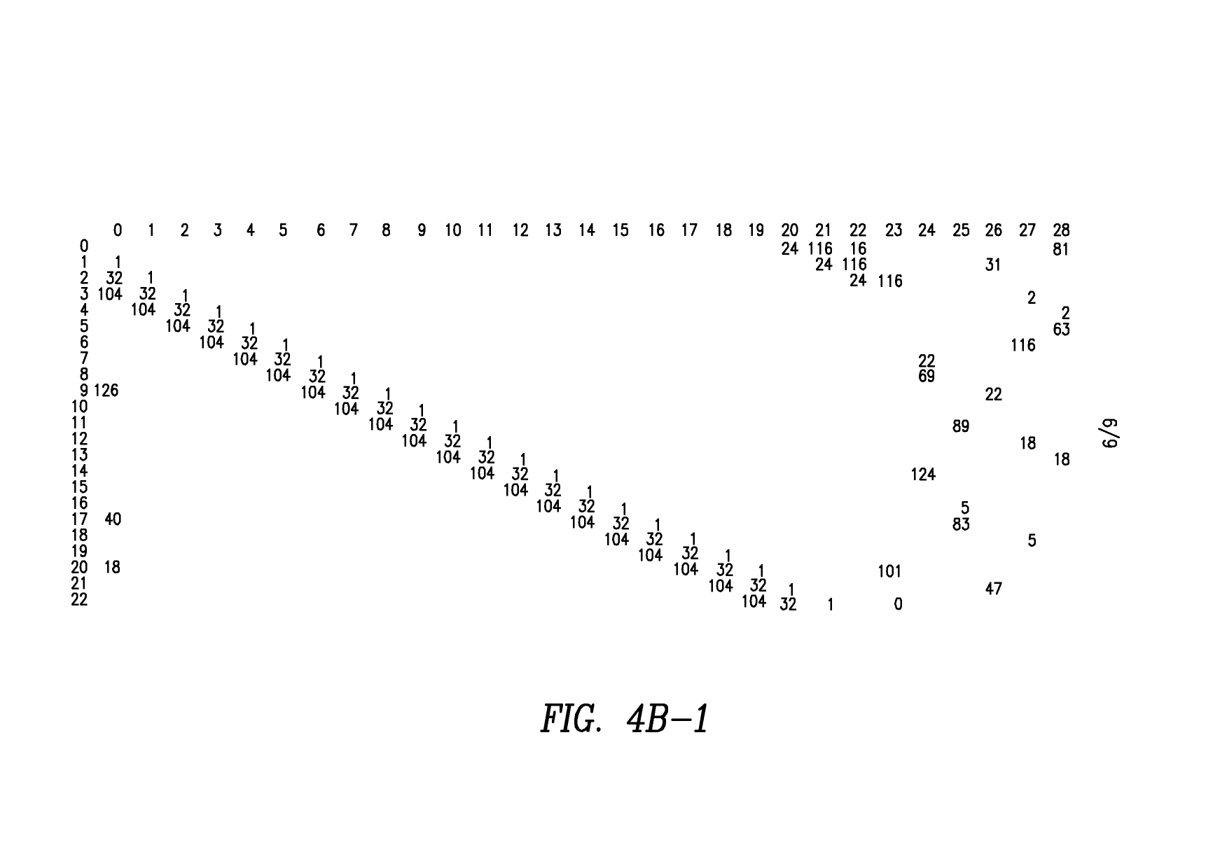

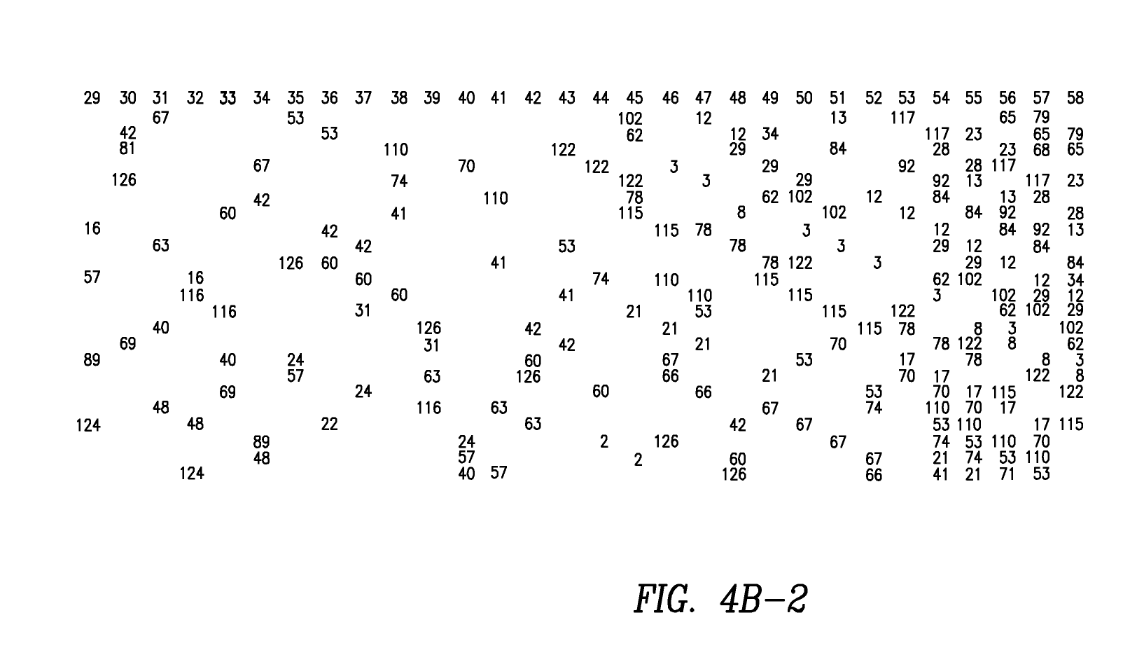

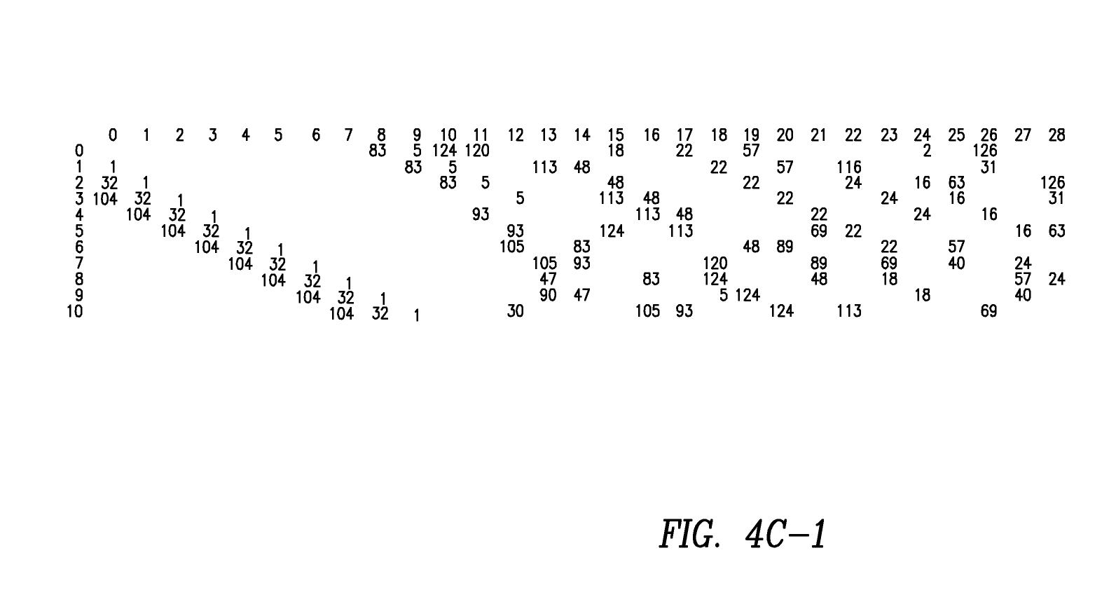

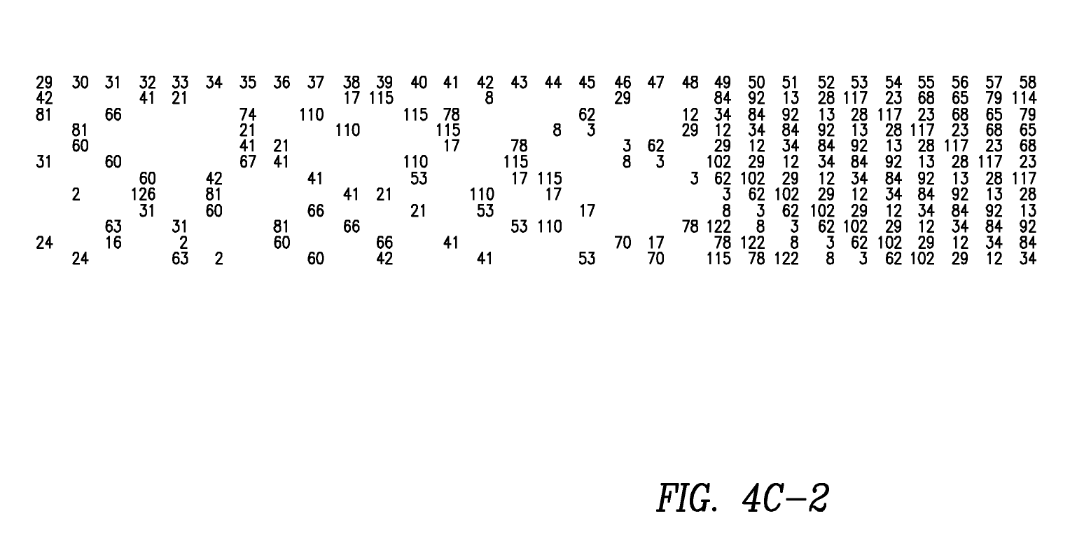

After the masking action, a resultant parity-check matrix H is obtained as shown in FIG. 2. Referring specifically to FIG. 2, the resultant parity-check matrix H has n rows and m columns, with both n, m being positive integers and m>n. Furthermore, resultant parity-check matrix H can be considered as a combination of a square matrix H_{sq} and a remainder Hᵣ. In other words, resultant parity-check matrix H=[H_{sq} Hᵣ]. That is a square matrix and a remainder matrix with the remainder matrix Hᵣ of higher degree than the square matrix H_{sq}. In H_{sq} on the diagonal line are all zero matrices. On the first sub-diagonal line, a series of identical cyclic permutation submatrices is provided. Similarly, on the second sub-diagonal line, a series of identical cyclic permutation submatrices is provided except different the positions for 1s are different from the first sub-diagonal line. On the third sub-diagonal line, a series of identical cyclic permutation submatrices is provided except having different positions for 1s that are different from the first and second sub-diagonal lines. For example, in FIG. 4A, for the first subdiagnal in the first row the position of the single 1 is in column 1 (note that the column numbers start from 0 to n−1). Similarly, in the second and third subdiagonals, in the first row the position of the single 1 is in columns 32 and 104 respectively. In other words, the masking matrix Z to a specific code has 1s on a series of three continuous sub-diagonals similar the sub-diagonals of H, i.e. aᵢⱼ, bᵢⱼ, and cᵢⱼ.

Referring to FIG. 3, a flowchart 60 of the present invention is shown. A plurality of sub-matrices is provided for forming a base matrix. Each sub-matrix is a cyclic permutation matrix (Step 62). Construct the base matrix using the plurality of sub-matrices (Step 64). Mask the base matrix using a small sparse matrix in a predetermined manner by selecting which elements within the base matrix should be kept and the rest not kept (Step 66). Use the masked base matrix as a parity-check matrix (Step 68).

Referring to FIGS. 4A-4C, a set of three exemplified parity check matrices constructed according to one aspect of the present invention is shown. Three different LDPC codes with different rates are generated in this exemplified DMB-TH system. They are (7493, 3048), (7493, 4572), and (7493, 6096) LDPC codes with rates 0.4, 0.6 and 0.8 respectively. The parity-check matrices of these three codes have quasi-cyclic structures and optimized degree distributions of bit nodes and check nodes of their corresponding Tanner graphs. The generation matrices G of these three LDPC codes are also quasi-cyclic. The generation matrices G can be encoded with shift-registers. The above three codes not only perform well with iterative decoding, but also achieve very low error floor in order to meet digital TV broadcasting requirements.

The construction of LDPC codes in LDPC BASED TDS-OFDM system is based on the minimum-weight codewords of Reed-Solomon codes. First, an H matrix (as shown in FIG. 1) for decoding is generated. The codes of the present invention are quasi-cyclic codes. Quasi-cyclic codes are linear codes for which cyclically shifting a codeword a fixed number of n₀ not equal to 1, and or a multiple of no of symbol positions either to the right, or to the left results in another codeword. Quasi-cyclic LDPC codes are known to have encoding advantages over other types of LDPC codes. They can be encoded in linear time using simple shift-registers with complexity linearly proportional to the length of the code for parallel encoding. The code and method of the present invention also optimizes the degree distributions of check nodes and bit nodes to make the error-floor lower than 10⁻¹².

In a LDPC based communications system, a method for generating LDPC codes is provided. The method comprises the steps of: constructing a base matrix; providing a plurality of sub-matrices for forming the base matrix, with each sub-matrix being a cyclic permutation matrix; and masking the base matrix using a small sparse matrix.

In a LDPC based communications system, a parity-check matrix is provided. The parity-check matrix comprises: a combination of a square matrix, and a remainder matrix. The square matrix comprises: a main diagonal line with all its elements therein being zero matrices; a first sub-diagonal line, immediately below the main diagonal line, being a series of identical cyclic permutation submatrices; a second sub-diagonal line, immediately below the first sub-diagonal line line, being a series of identical cyclic permutation submatrices having different positions for 1s than the series of identical cyclic permutation submatrices of the first sub-diagonal line; and a third sub-diagonal line, immediately below the second sub-diagonal line, being a series of identical cyclic permutation submatrices having different positions for 1s than the series of identical cyclic permutation submatrices of the first sub-diagonal line and second sub-diagonal line.

It is noted that the present invention contemplates using the PN sequence disclosed in U.S. Pat. No. 7,072,289 to Yang et al which is hereby incorporated herein by reference.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. In a LDPC based communications system, a method for generating LDPC codes comprising the steps of:
constructing a base matrix;
providing a plurality of sub-matrices for forming the base matrix, with each sub-matrix being a cyclic permutation matrix; and
masking the base matrix using a small sparse matrix.

2. The method of claim 1 further comprising the step of using the masked base matrix as a parity-check matrix.

3. The method of claim 1 further comprising the step of constructing a generation matrix with same derived from the parity-check matrix.

4. The method of claim 1, wherein the communications system comprises a LDPC based TDS-OFDM system.

5. The method of claim 1, wherein the masking step comprising the steps of:
providing a sparse masking matrix having a suitably designed distribution of 1-entries; and
generating a masked matrix.

6. The method of claim 1, wherein no two rows (or two columns) of the base matrix have more than one 1-component in common.

7. The method of claim 1, wherein the LDPC codes comprise structured LDPC codes.

8. The method of claim 1, wherein the LDPC codes comprise quasi-cyclic LDPC codes.

9. The method of claim 1, wherein the LDPC codes can be encoded using simple shift-registers with linear complexity.

10. The method of claim 1, wherein the parity-check matrix comprises an array of circulant permutation matrices having a same size as the base matrix.

11. The method of claim 1, wherein the parity-check matrix comprises:
a combination of a square matrix, and a remainder matrix; and
the square matrix comprising:
a main diagonal line with all its elements therein being zero matrices;
a first sub-diagonal line, immediately below the main diagonal line, being a series of identical cyclic permutation submatrices;
a second sub-diagonal line, immediately below the first sub-diagonal line line, being a series of identical cyclic permutation submatrices having different positions for 1s than the series of identical cyclic permutation submatrices of the first sub-diagonal line; and
a third sub-diagonal line, immediately below the second sub-diagonal line, being a series of identical cyclic permutation submatrices having different positions for is than the series of identical cyclic permutation submatrices of the first sub-diagonal line and second sub-diagonal line.

12. In a LDPC based communications system, a parity-check matrix comprises:
a combination of a square matrix, and a remainder matrix; and
the square matrix comprising:
a main diagonal line with all its elements therein being zero matrices;
a first sub-diagonal line, immediately below the main diagonal line, being a series of identical cyclic permutation submatrices;
a second sub-diagonal line, immediately below the first sub-diagonal line line, being a series of identical cyclic permutation submatrices having different positions for 1s than the series of identical cyclic permutation submatrices of the first sub-diagonal line; and
a third sub-diagonal line, immediately below the second sub-diagonal line, being a series of identical cyclic permutation submatrices having different positions for 1s than the series of identical cyclic permutation submatrices of the first sub-diagonal line and second sub-diagonal line.

13. The system of claim 12, wherein the remainder matrix comprises a matrix of higher degree than that of the square matrix.

14. The system of claim 12, wherein the rest of the square matrix comprises zeros except the last two columns of the first row and the last column of the second row.

15. The system of claim 12, wherein the parity-check matrix is derived from a base matrix.

16. The system of claim 12, wherein a plurality of sub-matrices form the base matrix.

17. The system of claim 12, wherein a masked base matrix forms the parity-check matrix.

18. The system of claim 12, wherein the parity-check matrix is used in a LDPC based TDS-OFDM communications system.

19. The system of claim 12, wherein the parity-check matrix comprises an array of circulant permutation matrices having a same size as the base matrix.

20. The system of claim 12, wherein the LDPC codes can be encoded using simple shift-registers with linear complexity.

21. The system of claim 12, wherein LDPC codes comprise quasi-cyclic LDPC codes.

22. The system of claim 12, wherein LDPC codes comprise structured LDPC codes.
